(19) United States
(12) Patent Application Publication
(10) Pub. No.: US 2026/0162947 A1
(43) Pub. Date: Jun. 11, 2026

(54) SUBSTRATE PROCESSING APPARATUS

(71) Applicant: SAMSUNG ELECTRONICS CO., LTD, Suwon-si (KR)

(72) Inventors: Kein KIM, Suwon-si (KR); Jiye KIM, Suwon-si (KR); Iksoo KIM, Suwon-si (KR)

(73) Assignee: SAMSUNG ELECTRONICS CO., LTD, Suwon-si (KR)

(21) Appl. No.: 19/183,265

(22) Filed: Apr. 18, 2025

(30) Foreign Application Priority Data
Oct. 25, 2024 (KR) 10-2024-0147930

(51) Int. Cl. H01J 37/32; H10P 72/72

(52) U.S. Cl. CPC H01J 37/32715; H01J 37/3244; H01J 2237/2007; H01J 2237/24585; H01J 2237/334; H10P 72/722

(57) ABSTRACT

A substrate processing apparatus may include: a chuck configured to support a substrate; a base plate configured to support the chuck; and a bonding layer between the chuck and the base plate, the bonding layer attaching the chuck to the base plate, wherein the chuck includes: a plurality of supports configured to contact the substrate; an accommodating body that accommodates the plurality of supports; at least one elastic body between the plurality of supports and the accommodating body; and at least one pressure sensor configured to measure pressure applied by the substrate to the plurality of supports, and wherein each of the plurality of supports is configured to individually move toward the base plate due to a weight of the substrate, based on a bent shape of the substrate.

### CROSS-REFERENCE TO RELATED APPLICATION

This application is based on and claims priority under 35 U.S.C. § 119 to Korean Patent Application No. 10-2024-0147930, filed on Oct. 25, 2024, in the Korean Intellectual Property Office, the disclosure of which is incorporated by reference herein in its entirety.

### BACKGROUND

### 1. Field

Some embodiments of the present disclosure relate to a substrate processing apparatus.

### 2. Description of Background Art

Electrostatic chucks are widely used as core equipment to stably fix a wafer and control a temperature in a semiconductor manufacturing process. Electrostatic chucks may perform a function of adsorbing a wafer by using an electrostatic force, and may precisely adjust a temperature of the wafer in the middle of a process. The function of electrostatic chucks is very important in a semiconductor manufacturing process. Particularly, in a process using plasma, the stable fixing of a wafer and the uniform control of a temperature may be directly associated with success in a process. Electrostatic chucks function as core equipment that

satisfies requirements. Recently, as the semiconductor industry advances, a size of a wafer increases, and a process is subdivided. Therefore, electrostatic chuck technology is continuously advancing, and technology for more precisely and efficiently controlling a wafer is being developed.

### SUMMARY

According to embodiments of the present disclosure, a substrate processing apparatus may be provided which may stably chuck a warped substrate.

According to embodiments of the present disclosure, a substrate processing apparatus may be provided and include: a chuck configured to support a substrate; a base plate configured to support the chuck; and a bonding layer between the chuck and the base plate, the bonding layer attaching the chuck to the base plate, wherein the chuck includes: a plurality of supports configured to contact the substrate; an accommodating body that accommodates the plurality of supports; at least one elastic body between the plurality of supports and the accommodating body; and at least one pressure sensor configured to measure pressure applied by the substrate to the plurality of supports, and wherein each of the plurality of supports is configured to individually move toward the base plate due to a weight of the substrate, based on a bent shape of the substrate.

According to embodiments of the present disclosure, a substrate processing apparatus may be provided and include: a chuck configured to support a substrate by using an electrostatic force; a base plate configured to support the chuck; and a bonding layer between the chuck and the base plate, the bonding layer attaching the chuck to the base plate, wherein the chuck includes: a plurality of supports configured to contact the substrate; an accommodating body that accommodates the plurality of supports; at least one displacement allower between the accommodating body and each of the plurality of supports, the at least one displacement allower configured to limit a vertical movement of each of the plurality of supports; and at least one pressure sensor configured to measure pressure applied to the plurality of supports by the substrate, and wherein each of the plurality of supports is configured to individually move toward the base plate due to a weight of the substrate, based on a bent shape of the substrate.

According to embodiments of the present disclosure, a substrate processing apparatus may be provided and include: a housing including a processing space configured for processing a substrate; a shower head in the housing and configured to supply an inner portion of the housing with a process gas for processing the substrate; a substrate support under the shower head, in the housing, the substrate support configured to support the substrate; and a plasma generator configured to generate plasma by using the process gas for processing the substrate, wherein the substrate support includes: a chuck configured to support the substrate; a base plate configured to support the chuck; and a bonding layer between the chuck and the base plate, the bonding layer attaching the chuck to the base plate, wherein the chuck includes: a plurality of supports configured to contact the substrate; an accommodating body configured to accommodate the plurality of supports; at least one displacement allower between the accommodating body and each of the plurality of supports, the at least one displacement allower configured to limit a vertical movement of each of the plurality of supports; at least one pressure sensor configured to measure pressure applied to the plurality of supports by the substrate; and a controller configured to calculate, based on pressure measured by the at least one pressure sensor based on a movement distance of each of the plurality of supports, a degree of bending of the substrate, and wherein each of the plurality of supports is configured to individually move toward the base plate due to a weight of the substrate, based on a bent shape of the substrate.

Aspects of embodiments of the present disclosure are not limited to the aspects mentioned above, and other objects not described herein will be clearly understood by those of ordinary skill in the art from the description below.

### BRIEF DESCRIPTION OF DRAWINGS

Embodiments will be more clearly understood from the following detailed description taken in conjunction with the accompanying drawings in which:

FIG. 1 is a cross-sectional view schematically illustrating a substrate processing apparatus according to an embodiment;

FIG. 2 is a cross-sectional view schematically illustrating an example of a substrate supporting unit of FIG. 1;

FIG. 3 is a plan view schematically illustrating an example of the substrate supporting unit of FIG. 1;

FIGS. 4A and 4B are cross-sectional views illustrating an operation of a chucking member of the substrate supporting unit of FIG. 2;

FIGS. 5A to 5C are cross-sectional views illustrating a process of chucking a substrate by using the substrate supporting unit of FIG. 1;

FIG. 6 is a cross-sectional view schematically illustrating an example of the substrate supporting unit of FIG. 1; and

FIGS. 7A and 7B are cross-sectional views illustrating an operation of a chucking member of the substrate supporting unit of FIG. 6.

### DETAILED DESCRIPTION

Hereinafter, non-limiting example embodiments of the present disclosure will be described in detail with reference to the accompanying drawings. However, embodiments of the present disclosure are not limited to the example embodiments described below, and may include different forms. The following example embodiments are provided to sufficiently describe the scope of the present disclosure to those of ordinary skill in the art, rather than for purposes of limitation.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

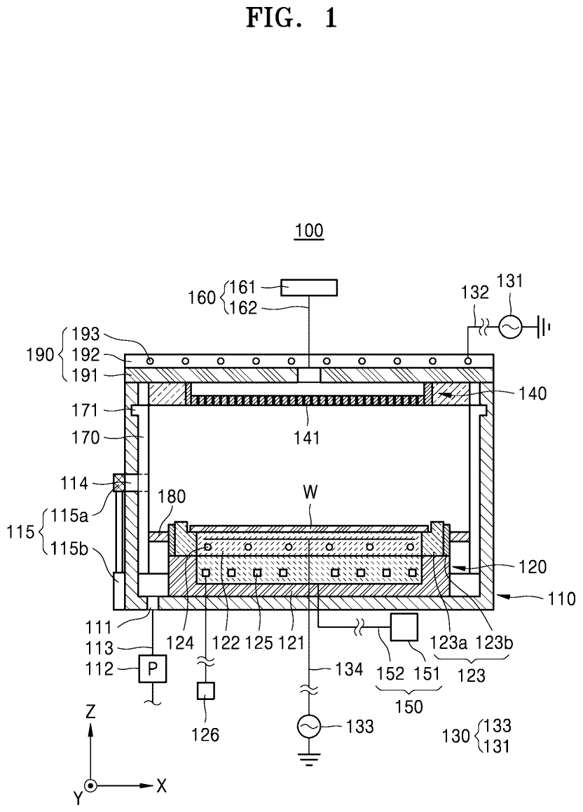

FIG. 1 is a cross-sectional view schematically illustrating a structure of a substrate processing apparatus 100 according to an embodiment.

Referring to FIG. 1, the substrate processing apparatus 100 may include a housing 110, a substrate supporting unit 120 (e.g., a substrate support), a plasma generating unit 130 (e.g., a plasma generator), a shower head unit 140 (e.g., a shower head), a first gas supply unit 150 (e.g., a first gas supply), a second gas supply unit 160 (e.g., a second gas supply), a wall liner unit 170 (e.g., a wall liner), a baffle unit 180 (e.g., a baffle), and an upper module 190.

The substrate processing apparatus 100 may be an apparatus which processes a substrate W by using an etching process (e.g., a dry etching process) in a vacuum environment. The substrate processing apparatus 100 may process, for example, the substrate W by using a plasma process.

The housing 110 may provide a space where the plasma process is performed. The housing 110 may include an exhaust hole 111 which is provided in a lower portion thereof.

The exhaust hole 111 may be connected to an exhaust line 113 with a pump 112 equipped therein. The exhaust hole 111 may emit, to the outside of the housing 110 through the exhaust line 113, a reaction byproduct occurring in a plasma process and a gas remaining in the housing 110. In this case, an internal space of the housing 110 may be pressed with certain pressure.

An opening portion 114 (e.g., an opening) may be formed in a sidewall of the housing 110. The opening portion 114 may function as a path through which the substrate W is loaded/unloaded to/from an inner portion of the housing 110. The opening portion 114 may be configured to be opened or closed by a door assembly 115.

The door assembly 115 may include an outer door 115a and a door driver 115b. The outer door 115a may be provided at an outer wall of the housing 110. The outer door 115a may move in a vertical direction (e.g., a Z direction) by being driven by the door driver 115b. The door driver 115b may include, for example, a motor, a hydraulic cylinder, or a pneumatic cylinder.

The substrate supporting unit 120 may be installed in an inner lower region of the housing 110. The substrate supporting unit 120 may support the substrate W by using an electrostatic force. However, embodiments of the present disclosure are not limited thereto. The substrate supporting unit 120 may support the substrate W by using various methods such as mechanical clamping and a vacuum.

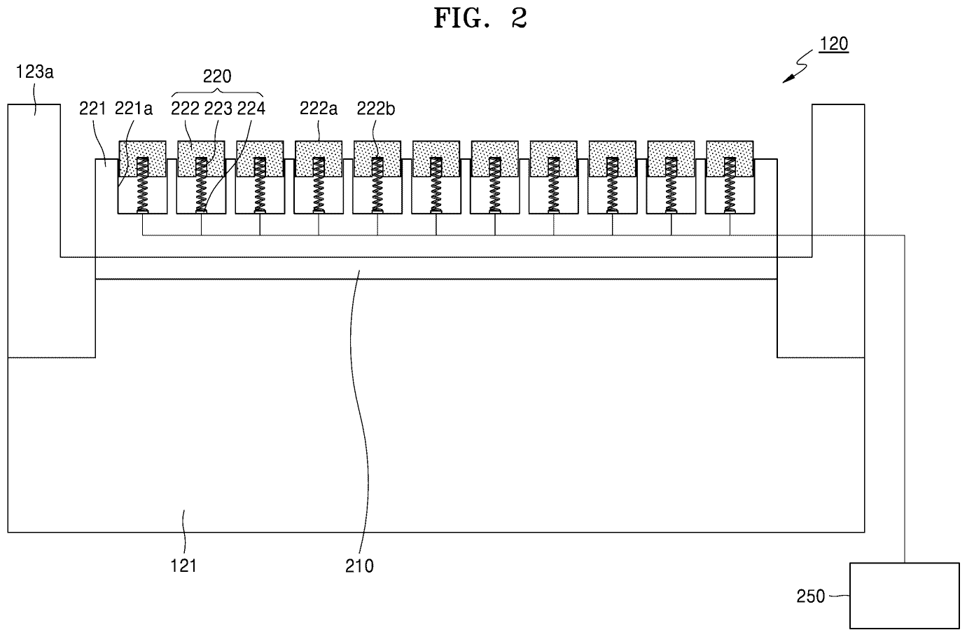

In a case where the substrate supporting unit 120 supports the substrate W by using an electrostatic force, the substrate supporting unit 120 may be implemented as an electrostatic chuck (ESC) including a base plate 121 and a chucking member 220 (e.g., a chuck) (see FIG. 2).

The base plate 121 may support the chucking member 220. The base plate 121 may include, for example, an aluminum component and may be provided as an aluminum (Al) base plate.

The chucking member 220 may support the substrate W mounted thereon by using an electrostatic force. The chucking member 220 may include a ceramic component and may be provided as a ceramic plate or a ceramic puck, and moreover, may be coupled to the base plate 121 so as to be fixed to the base plate 121.

The chucking member 220 may include a plurality of supporting units 222 (e.g., supports). The substrate W may be mounted on the plurality of supporting units 222. The plurality of supporting units 222 may be individually lowered in a direction (e.g., a −Z-axis direction) toward the base plate 121, based on a bent appearance of the substrate W by a weight of the substrate W mounted thereon. When the substrate W is raised off of the plurality of supporting unit 222, the lowered plurality of supporting units 222 may return to original positions. This will be described below.

A bonding layer 210 (see FIG. 2) may be formed between the base plate 121 and the chucking member 220 formed thereon, and a bonding protection member may be installed at an outer portion of the bonding layer 210 so as to protect the bonding layer 210. The bonding layer 210 and the bonding protection member will be described below in more detail.

The chucking member 220 may be installed in the housing 110, and may be provided with a driving member (e.g., an actuator) so as to be movable in a vertical direction (e.g., a Z direction). In a case where the chucking member 220 is formed to be movable in the vertical direction (e.g., the Z direction), the substrate W may be disposed in a region representing a uniform plasma distribution.

A ring assembly 123 may be provided to surround an edge of the chucking member 220. The ring assembly 123 may be provided in a ring shape and may be configured to support an edge region of the substrate W. The ring assembly 123 may include a focus ring 123a and an insulation ring 123b.

The focus ring 123a may be formed at an inner side of the insulation ring 123b and may be provided to surround the chucking member 220. The focus ring 123a may include a silicon material and may allow plasma to concentrate on the substrate W.

The insulation ring 123b may be formed at an outer side of the focus ring 123a and may be provided to surround the focus ring 123a. The insulation ring 123b may include a quartz material.

Furthermore, the ring assembly 123 may further include an edge ring which is closely formed at an edge of the focus ring 123a. The edge ring may be formed for preventing a side surface of the chucking member 220 from being damaged by plasma.

The first gas supply unit 150 may supply a first gas so as to remove a foreign material remaining in an upper portion of the ring assembly 123 or an edge portion of the chucking member 220. The first gas supply unit 150 may be configured to include a first gas supply source 151 and a first gas supply line 152.

The first gas supply source 151 may supply a nitrogen (N₂) gas as the first gas. However, embodiments of the present disclosure are not limited thereto. The first gas supply source 151 may supply another gas or cleaning agent.

The first gas supply line 152 may be provided between the chucking member 220 and the ring assembly 123. For example, the first gas supply line 152 may be connected between the chucking member 220 and the focus ring 123a.

Also, the first gas supply line 152 may be provided in the focus ring 123a and may be connected between the chucking member 220 and the focus ring 123a.

A heating member 124 (e.g., a heater) and a cooling member 125 (e.g., a cooler) may be provided so that the substrate W maintains a process temperature when an etching process is being performed in the housing 110. To this end, the heating member 124 may be provided as a heating wire, and the cooling member 125 may be provided as a cooling line through where a refrigerant flows.

The heating member 124 and the cooling member 125 may be installed in the substrate supporting unit 120 so that the substrate W maintains the process temperature. For example, the heating member 124 may be installed in the chucking member 220, and the cooling member 125 may be installed in the base plate 121.

Also, the cooling member 125 may be supplied with the refrigerant by using a cooling apparatus 126 (e.g., a refrigerant supply). The cooling apparatus 126 may be installed outside the housing 110.

The plasma generating unit 130 may generate plasma from a gas remaining in a discharge space. Here, the discharge space may be a space, disposed on the substrate supporting unit 120, of an internal space of the housing 110.

The plasma generating unit 130 may generate plasma in the discharge space of the housing 110 by using an inductively coupled plasma (ICP) source. In this case, the plasma generating unit 130 may use, as an upper electrode, an antenna unit 193 (e.g., an antenna) installed in the upper module 190 and may use the substrate supporting unit 120 as a lower electrode.

However, embodiments of the present disclosure are not limited thereto. The plasma generating unit 130 may generate plasma in the discharge space of the housing 110 by using a capacitively coupled plasma (CCP) source. In this case, the plasma generating unit 130 may use the shower head unit 140 as an upper electrode and may use the substrate supporting unit 120 as a lower electrode.

The plasma generating unit 130 may be configured to include an upper electrode, a lower electrode, an upper power source 131, and a lower power source 133. The upper power source 131 may apply power to the upper electrode (i.e., the antenna unit 193). The upper power source 131 may be provided to control a characteristic of plasma. The upper power source 131 may be provided, for example, to adjust ion bombardment energy.

The upper power source 131 is illustrated as one power source in FIG. 1, but is not limited thereto and may be provided in plural. When the upper power source 131 is provided in plural, the substrate processing apparatus 100 may further include a first matching network which is electrically connected to the plurality of upper power sources 131.

The first matching network may match frequency powers having different levels respectively input from the upper power sources 131 to apply to the antenna unit 193. Also, a first impedance matching circuit for impedance matching may be provided in a first transfer line 132 connecting the upper power source 131 to the antenna unit 193. The first impedance matching circuit may operate as a lossless passive circuit to allow electric energy to be effectively (e.g., maximally) transferred from the upper power source 131 to the antenna unit 193.

The lower power source 133 may apply power to the lower electrode (e.g., the substrate supporting unit 120). The lower power source 133 may function as a plasma source which generates plasma, or may control a characteristic of plasma along with the upper power source 131.

The lower power source 133 is illustrated as one in FIG. 1, but is not limited thereto and in some embodiments of the present disclosure, like the upper power source 131, the lower power source 133 may be provided in plural. In a case where the lower power source 133 is provided in plural, the substrate processing apparatus 100 may further include a second matching network which is electrically connected to the plurality of lower power sources 133.

The second matching network may match frequency powers having different levels respectively input from the lower power sources 133 to apply to the substrate supporting unit 120. Also, a second impedance matching circuit for impedance matching may be provided in a second transfer line 134 connecting the lower power source 133 to the substrate supporting unit 120. The second impedance matching circuit, like the first impedance matching circuit, may operate as a lossless passive circuit to allow electric energy to be effectively (e.g., maximally) transferred from the lower power source 133 to the substrate supporting unit 120.

The shower head unit 140 may be installed to be vertically opposite to the substrate supporting unit 120, in the housing 110. The shower head unit 140 may include a plurality of gas feeding holes 141 so as to feed a gas into the housing 110 and may be provided to have a diameter which is greater than that of the substrate supporting unit 120. Also, the shower head unit 140 may include a silicon component, and moreover, may include a metal component.

The second gas supply unit 160 may supply a process gas (e.g., a second gas) into the housing 110 through the shower head unit 140. The second gas supply unit 160 may include a second gas supply source 161 and a second gas supply line 162.

The second gas supply source 161 may supply, as the process gas, an etching gas used to process the substrate W. The second gas supply source 161 may supply, as the etching gas, a gas (e.g., a gas such as SF₆ or CF₄) including a fluorine component. The second gas supply source 161 may be provided as one gas supply source and may supply the etching gas to the shower head unit 140. However, embodiments of the present disclosure are not limited thereto. The second gas supply source 161 may be provided in plural and may supply the process gas to the shower head unit 140.

The second gas supply line 162 may connect the second gas supply source 161 to the shower head unit 140. The second gas supply line 162 may transfer the process gas, supplied through the second gas supply source 161, to the shower head unit 140 and may thus allow the etching gas to flow into the housing 110.

In a case where the shower head unit 140 is divided into a center zone, a middle zone, and an edge zone, the second gas supply unit 160 may further include a gas distributor and a gas distribution line, so as to supply the process gas to each zone of the shower head unit 140.

The gas distributor may distribute the process gas, supplied from the second gas supply source 161, to each zone of the shower head unit 140. The gas distributor may be connected to the second gas supply source 161 through the second gas supply line 162.

The gas distribution line may connect the gas distributor to each zone of the shower head unit 140. Therefore, the gas distribution line may transfer the process gas, distributed by the gas distributor, to each zone of the shower head unit 140.

Also, the second gas supply unit 160 may further include a third gas supply source which supplies a deposition gas.

The third gas supply source may protect a side surface of a substrate W pattern and may supply the deposition gas to the shower head unit 140 so as to enable anisotropic etching. The second gas supply source may supply, as the deposition gas, a gas such as C₄F₈ or C₂F₄.

The wall liner unit 170 may be for protecting an inner surface of the housing 110 from impurities occurring in a substrate processing process and arc discharge occurring in a process of exciting the process gas. The wall liner unit 170 may be provided in a cylindrical shape where each of an upper portion and a lower portion of the cylindrical shape is opened in the housing 110.

The wall liner unit 170 may be provided to be adjacent to an inner sidewall of the housing 110. The wall liner unit 170 may include a supporting ring 171 which is provided in an upper portion thereof. The supporting ring 171 may be formed to protrude in an outward direction (e.g., an X direction) from the upper portion of the wall liner unit 170 and may be disposed at an upper end of the housing 110 to support the wall liner unit 170.

The baffle unit 180 may exhaust an unreacted gas or a process byproduct of plasma. The baffle unit 180 may be installed between the substrate supporting unit 120 and the inner sidewall of the housing 110. The baffle unit 180 may be provided in a circular ring shape and may include a plurality of through holes which pass through the baffle unit 180 in a vertical direction (e.g., a Z direction). The baffle unit 180 may control a flow of the process gas, based on the number and shape of through holes.

The upper module 190 may be installed to cover an opened upper portion of the housing 110. The upper module 190 may include a window member 191 (e.g., a window), an antenna member 192, and an antenna unit 193 (e.g., an antenna).

The window member 191 may be formed to cover the upper portion of the housing 110 so as to close an internal space of the housing 110. The window member 191 may be provided in a plate (e.g., a disc) shape and may include an insulating material (e.g., Al₂O₃). The window member 191 may be formed to include a dielectric window, a through hole into which the second gas supply line 162 is inserted may be formed in the window member 191, and a coating film may be formed on a surface of the window member 191 so as to prevent the occurrence of particles when a plasma process is being performed in the housing 110.

The antenna member 192 may be installed on the window member 191, and a space having a certain size may be provided so that the antenna unit 193 is disposed therein. The antenna member 192 may be formed in a cylindrical shape where a lower portion is opened and may be provided to have a diameter corresponding to the housing 110. The antenna member 192 may be provided to be attached/detached to/from the window member 191.

The antenna unit 193 may function as an upper electrode, and a coil provided to form a closed loop may be equipped in the antenna unit 193. The antenna unit 193 may generate a magnetic field and an electric field in the housing 110, based on power supplied from the upper power source 131, and may excite a gas, flowing into the housing 110, to plasma through the shower head unit 140. The antenna unit 193 may be equipped with a coil of a planar spiral type. However, embodiments of the present disclosure are not limited thereto. A structure or a size of the coil may be variously modified by one of ordinary skill in the art.

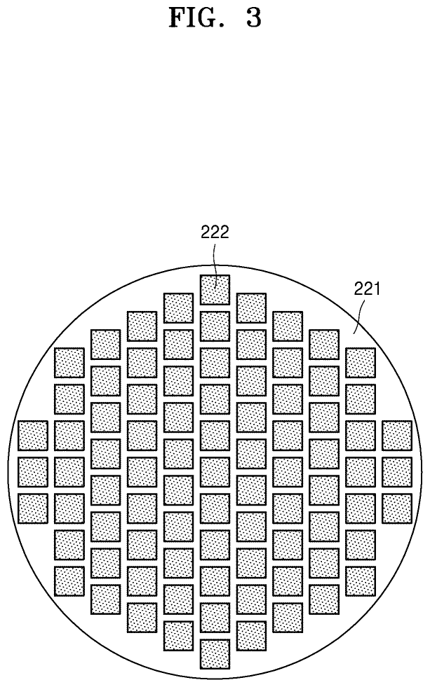

The substrate processing apparatus 100 according to an embodiment may stably chuck a bent substrate through the substrate supporting unit 120. The substrate supporting unit 120 will be described below in more detail with reference to FIGS. 2 and 3.

FIGS. 2 and 3 are a cross-sectional view and a plan view schematically illustrating an example of the substrate supporting unit 120 of FIG. 1, respectively. FIGS. 2 and 3 may be described with reference to FIG. 1, and descriptions which are the same as or similar to the descriptions of FIG. 1 may be briefly given below or may not be repeated.

Referring to FIGS. 2 and 3, the substrate supporting unit 120 may include the base plate 121, the chucking member 220, and the bonding layer 210.

The chucking member 220 may include, for example, the plurality of supporting units 222, a body unit 221 (e.g., an accommodating body), an elastic unit 223 (e.g., an elastic body), a pressure sensing unit 224 (e.g., a pressure sensor), and a control unit 250 (e.g., a controller).

The plurality of supporting units 222 may support a substrate W in direct contact with the substrate W. The plurality of supporting units 222 may individually move toward the base plate 121, based on a bent appearance of the substrate W by a weight of the substrate W. Even when the substrate W is bent or strained, the plurality of supporting units 222 may uniformly support the entire substrate W.

When the pressing of the plurality of supporting units 222 by the substrate W is released, the plurality of supporting units 222 may return to original positions due to the elastic unit 223.

Each of the plurality of supporting units 222 may include an upper surface 222a directly contacting the substrate W, a lower surface disposed to be opposite to the upper surface 222a, and a side surface connecting the upper surface to the lower surface. The upper surface 222a of the supporting unit 222 may be formed to be flat, and the substrate W may be stably mounted thereon.

A groove 222b may be formed in the supporting unit 222. The groove 222b may be recessed by a certain depth from a lower surface of the supporting unit 222 in a direction toward the upper surface 222a. The elastic unit 223 may be disposed in the groove 222b, and thus, the supporting unit 222 may elastically move in a vertical direction. A depth and a width of the groove 222b may be optimized based on a size and an elastic characteristic of the elastic unit 223 used.

The supporting unit 222 may include, for example, a ceramic material such as alumina (Al₂O₃), aluminum nitride (AlN), or ytterbium oxide (Y₂O₃). The ceramic material may be good in heat resistance, corrosion resistance, and anti-abrasion and may be suitable for use in a plasma environment. Also, the upper surface 222a of the supporting unit 222 may be precisely processed to minimize surface roughness, and thus, a contact area with a substrate may be maximized and heat transfer efficiency may be enhanced.

A cross-sectional shape of the supporting unit 222 may be variously implemented as a cylindrical shape, a multi-angle pillar shape, or a truncated-cone shape, and may be optimized based on a size and a weight of a substrate and a characteristic of a processing process. For example, a truncated-cone supporting unit may minimize an area of an upper surface and may provide a stable supporting force, and thus, may be favorable to processing of a large-area substrate.

A fine vacuum hole may be formed in a center of the upper surface 222a of each supporting unit 222. The vacuum hole may be formed to pass through an inner portion of the supporting unit 120 and may be connected to an external vacuum source to vacuum-adsorb the substrate W. Accordingly, a substrate may be stably fixed, and moreover, heat transfer efficiency between a substrate backside and a supporting unit may be enhanced.

The number and arrangement of supporting units 222 may be optimized based on a size and a shape of a substrate. Generally, the supporting unit 222 may be disposed to have a uniform distribution on a substrate area and may be densely disposed near an edge of a substrate. Therefore, the occurrence of a sag or a strain in a substrate edge may be effectively prevented.

A structure of a supporting unit (e.g., the supporting unit 222) according to an embodiment of the present disclosure may actively respond to the sag or strain of a substrate, and thus, may provide a uniform supporting force all over a substrate. Accordingly, uniformity of substrate processing may be enhanced, damage of a substrate may be prevented, and a process yield rate may increase.

The body unit 221 may be a structure which accommodates the plurality of supporting units 222 and may be configured so that each supporting unit 222 moves in a vertical direction. The body unit 221 may include a plurality of accommodating spaces 221a. Each of the accommodating spaces 221a may be designed to accurately correspond to a shape of an individual supporting unit 222, and thus, may allow the vertical-direction movement of the supporting unit 222 and may limit the side-direction movement of the supporting unit 222. An inner wall of the accommodating space 221a may be processed with the surface roughness of a nanometer level, and thus, may minimize friction with the supporting unit 222 and may prevent the occurrence of fine dust.

The body unit 221 may include the same ceramic material as a ceramic material of the supporting unit 222, and for example, may include Al₂O₃, AlN, or Y₂O₃. Because the body unit 221 and the supporting unit 222 includes the same ceramic material, thermal stress may be minimized through matching of a coefficient of thermal expansion, and heat resistance and corrosion resistance in a plasma environment may be guaranteed. Particularly, AlN may be good in heat dispersion effect, based on good thermal conductance (about 170 W/m·K), and thus, may effectively control heat occurring in substrate processing.

The elastic unit 223 may be disposed between the supporting unit 222 and the body unit 221 and may elastically support the movement of the supporting unit 222.

The elastic unit 223 may be a spring or an elastic rubber. The spring may include, for example, an ultra-high-strength nickel alloy such as Inconel or Elgiloy. Such a material may maintain a good elastic characteristic and corrosion resistance in a high temperature environment and may guarantee fatigue lifetime. The elastic rubber may include, for example, a fluoro-rubber or perfluoro-rubber-based high functional elastomer. The high functional elastomer may maintain stable elasticity at a high temperature of about 250° C. or more and may be good in chemical resistance in a plasma environment.

The elastic unit 223 may allow the supporting unit 222 to be precisely pressed based on an appearance of a substrate. For example, when a center portion of a 300 μm wafer is maximally bent by about 50 μm, supporting units of the center portion may be maximally lowered by about 50 μm, based thereon, and may have a displacement which decreases progressively toward a peripheral portion. Such a dynamic adaptive mechanism may provide a uniform supporting force all over a substrate, and thus, may prevent the concentration of stress and may minimize a damage risk of a substrate.

When a substrate is removed in the supporting unit 222, the supporting unit 222 may return to an original position, based on a restoring force of the elastic unit 223. A time constant (τ) of such a restoration process may be generally controlled within a range of about 10 msec to about 100 msec, and thus, a next substrate W may be quickly loaded. An overshoot or a vibration occurring in a restoration process may be minimized through a precisely designed damping mechanism.

To maintain the performance of the elastic unit 223, a micro-scale displacement sensor may be integrated into each elastic element. The displacement sensor may apply a piezoelectric resistant type or a capacitive type, and thus, may measure a displacement of a nanometer level in real time. Measured data may be transferred to the control unit 250, and thus, a position and a load state of each supporting unit 222 may be continuously monitored, and a correction operation may be performed depending on the case.

The elastic unit 223 may be designed based on thermal stability. Material selection and structure optimization may be performed so that a change in elastic characteristic is within a range of about ±5%, in an operation temperature range (e.g., −40° C. to 620° C.) . Depending on the case, a heat shield structure or an active cooling system may be integrated into a periphery of the elastic unit 223, and thus, stable performance may be guaranteed in an extreme temperature condition.

The pressure sensing unit 224 may be disposed under each elastic unit 223 and may measure pressure applied to the supporting unit 222 by the substrate W in real time.

The pressure sensing unit 224 may include, for example, a high-sensitivity piezoelectric element or a capacitive pressure sensor. The piezoelectric element may sense a fine force of a 10-6 N level by using a high-performance piezoelectric material such as quartz or lithium niobate (LiNbO₃). A capacitive sensor may be manufactured by using micro-electro-mechanical system (MEMS) technology and may measure a pressure variation with a resolution of about 0.1 Pa.

The pressure sensing unit 224 may independently operate based on the individual supporting unit 222, and thus, may map a high space resolution to a pressure distribution all over a substrate. A dynamic range of a sensor may be set to, for example, a range of about 0.1 N to about 100 N and may accommodate substrates having various sizes and weights.

The control unit 250 may process in real time pressure data measured by the pressure sensing unit 224 and a movement distance of the supporting unit 222 to calculate the degree of bending of a substrate.

The control unit 250 may be equipped with a high-performance microprocessor and an accurate algorithm and may analyze data measured from the pressure sensing unit 224 in real time. Accordingly, the control unit 250 may precisely calculate the movement distance of the supporting unit 222 and may monitor a three-dimensional shape change of a substrate with an accuracy of a micrometer level.

According to embodiments of the present disclosure, the control unit 250 (e.g., a controller) may include at least processor (e.g., at least one microprocessor) and memory storing computer instructions. The computer instructions, when executed by the at least one processor, may be configured to cause the control unit 250 to perform its functions.

The control unit 250 may, for example, calculate the degree of bending of a substrate through the following algorithm.

First, the control unit 250 may remove noise of a sensor signal and may extract a significant change by using a Kalman filter and a wavelet transform in a data preprocessing process.

Subsequently, the control unit 250 may precisely map a relationship between a movement distance and pressure measured in each supporting unit 222 by using a nonlinear spring model. In such a process, a finite element method (FEM) may be applied in real time, and an interaction between the supporting units 222 may be considered.

Subsequently, the control unit 250 may synthesize data of each supporting unit 222 to reconfigure a three-dimensional (3D) shape of an entire substrate W. The control unit 250 may estimate a zone between pressure sensing units 224 with high accuracy by using a thin-plate spline interpolation method.

The control unit 250 may calculate parameters such as a maximum displacement, a curvature radius, and bending energy in a reconfigured 3D profile to quantify the degree of bending of a substrate at a multiangle.

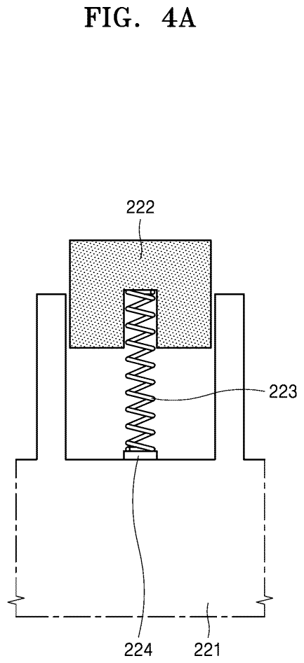

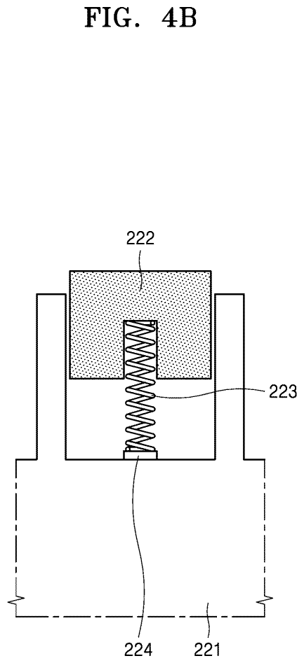

FIGS. 4A and 4B are cross-sectional views illustrating an operation of the chucking member of the substrate supporting unit of FIG. 2.

Referring to FIG. 4A, an initial state of the chucking member 220 is illustrated. In an initial state of the chucking member 220, the plurality of supporting units 222 may be disposed at positions maximally protruding from the body unit 221. Each supporting unit 222 may be disposed in the accommodating space 221a formed in the body unit 221 and may be supported by the elastic unit 223. The pressure sensing unit 224 may be disposed under the elastic unit 223. In this state, the substrate W may not yet be loaded onto the chucking member 220, or may be just loaded and may be in a state immediately before contacting the supporting unit 222.

An upper surface of each supporting unit 222 may configure a precisely polished flat surface, and heights thereof may be equally maintained. This may be a state which is ready for accommodating an ideal substrate having complete flatness. A fine gap may be maintained between a side surface of the supporting unit 222 and an inner wall of the accommodating space 221a, and movement in a lateral direction may not be limited without hindering a vertical motion of the supporting unit 222.

Referring to FIG. 4B, a state after the substrate W is completely loaded onto the chucking member 220 is illustrated. For example, in this state, a center of the substrate W may be bent to be downward convex. Based on a shape change of a substrate, each supporting unit 222 may be individually lowered based on a curvature of the substrate W.

In detail, a supporting unit 222 disposed at a center may be lowered with a largest displacement in comparison to a supporting unit 222 disposed away from the center, and the degree to which the supporting unit 222 is lowered may decrease progressively toward an outer portion. This may show that each supporting unit 222 is accurately based on a local height change of the substrate W. The differential lowering of the supporting units 222 may be performed by an elastic strain of the elastic unit 223.

The elastic unit 223 may be compressed as each supporting unit 222 is lowered, and thus, the pressure sensing unit 224 may sense an increased pressure. Pressure data measured by the pressure sensing unit 224 and displacement information about the supporting unit 222 may be transferred to the control unit 250 and may be used to precisely reconfigure a 3D shape of the substrate W.

Based on such a structure, the chucking member 220 according to an embodiment may dynamically respond to a change in shape such as the bending or warpage of the substrate W. As a result, a uniform supporting force may be provided to the entire substrate W, and thus, in a subsequent process, uniformity may be enhanced, and a damage risk of a substrate may decrease.

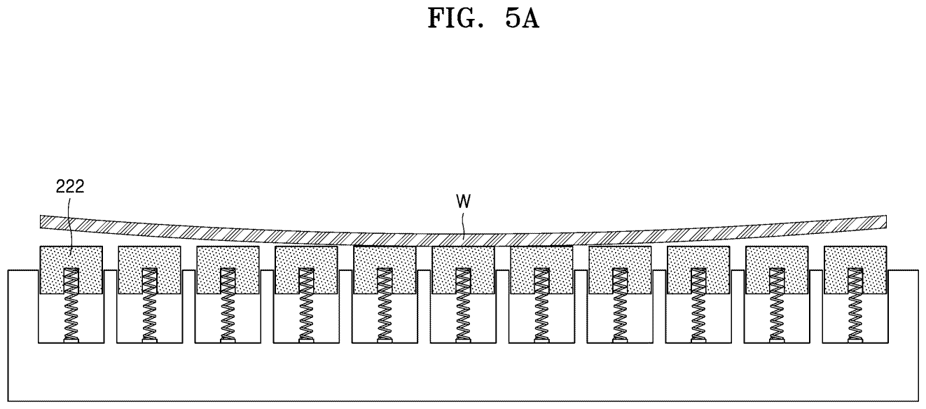

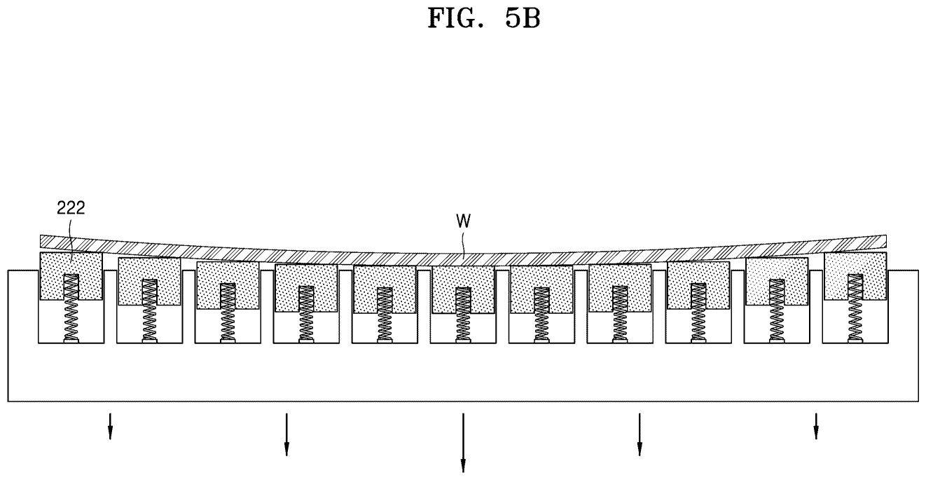

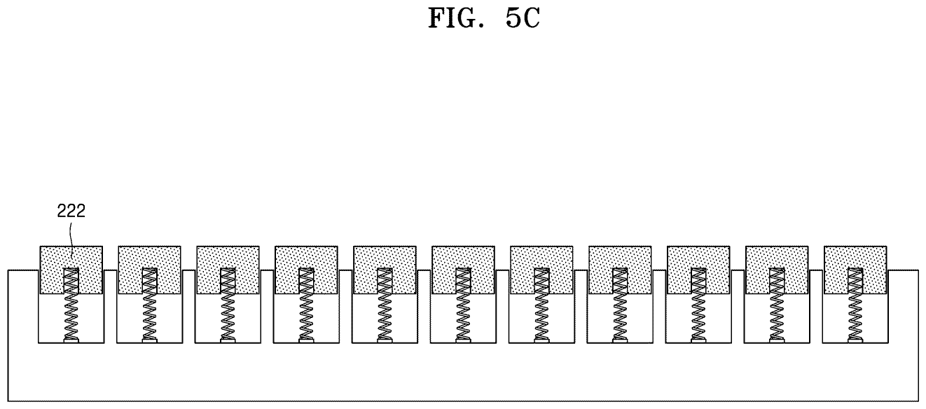

FIGS. 5A to 5C are cross-sectional views illustrating a process of chucking a substrate W by using the substrate supporting unit 120 of FIG. 1.

Referring to FIG. 5A, an initial state where a substrate W having a bent shape is disposed on the substrate supporting unit 120 is illustrated. In this step, a center portion of the substrate W may be bent to be downward convex, and the substrate W may not fully contact the substrate supporting unit 120a.

In this state, all supporting units 222 may protrude by the same height, and the elastic unit 223 may maintain a relaxed state. The pressure sensing unit 224 may not sense a change in pressure. The pressure sensing unit 224 may be apart from, by a certain distance, a supporting unit 222 disposed at an outer portion, corresponding to (e.g., overlapping with) an edge portion, of the substrate W and may contact a supporting unit 222 corresponding to (e.g., overlapping with) the center portion of the substrate W.

FIG. 5B illustrates a state where a substrate W is completely chucked on the substrate supporting unit 120a. In this step, the substrate W may be fixed to the substrate supporting unit 120a by an electrostatic force. Each supporting unit 222 may be individually displaced based on a bent shape of the substrate W.

In detail, a supporting unit 222 disposed at a center portion of the substrate W may have a largest down displacement, and thus, an elastic unit 223 at a corresponding position may be most compressed. A supporting unit 222 at a position between the center portion and an edge of the substrate W may have a displacement of a middle level, and a supporting unit 222 at the edge of the substrate W may have a minimum displacement. Based on a differential displacement, the supporting unit 222 may provide a uniform supporting force to an entire area of the substrate W corresponding to a bent shape of the substrate W.

The pressure sensing unit 224 disposed under each supporting unit 222 may measure different pressure values at this time. A pressure sensing unit 224 at the center e.g., a centermost pressure sensing unit 224) may sense a highest pressure, and a pressure sensing unit 224 at the edge (e.g., an outermost pressure sensing unit 224) may sense a lowest pressure. Pressure data may be transferred to the control unit 250 and may be used to calculate an accurate shape of the substrate W.

FIG. 5C illustrates a state immediately after a substrate W is removed in the substrate supporting unit 120a. In this step, each supporting unit 222 may return to an original position with a restoring force of the elastic unit 223.

A supporting unit 222 of a center portion (e.g., the centermost pressure sensing unit 224) may move in an upward direction with a largest displacement. A supporting unit 222 at the center position portion (e.g., the centermost pressure sensing unit 224) and a supporting unit 222 at the edge portion (e.g., the outermost pressure sensing unit 224) may return to original positions at different speeds. This may be a phenomenon which occurs because the degree of compression of each supporting unit 222 differs and may be determined based on a damping effect and a characteristic of the elastic unit 223.

At this time, the pressure sensing unit 224 may sense a reduction in pressure, and pressure data may be transferred to the control unit 250. Such a dynamic restoration process may be precisely controlled to be changed to a loading preparation state of a next substrate.

Through a series of processes described above, the substrate supporting unit 120 according to an embodiment may stably support a bent substrate W and may quickly return to a preparation state for a next operation after processing.

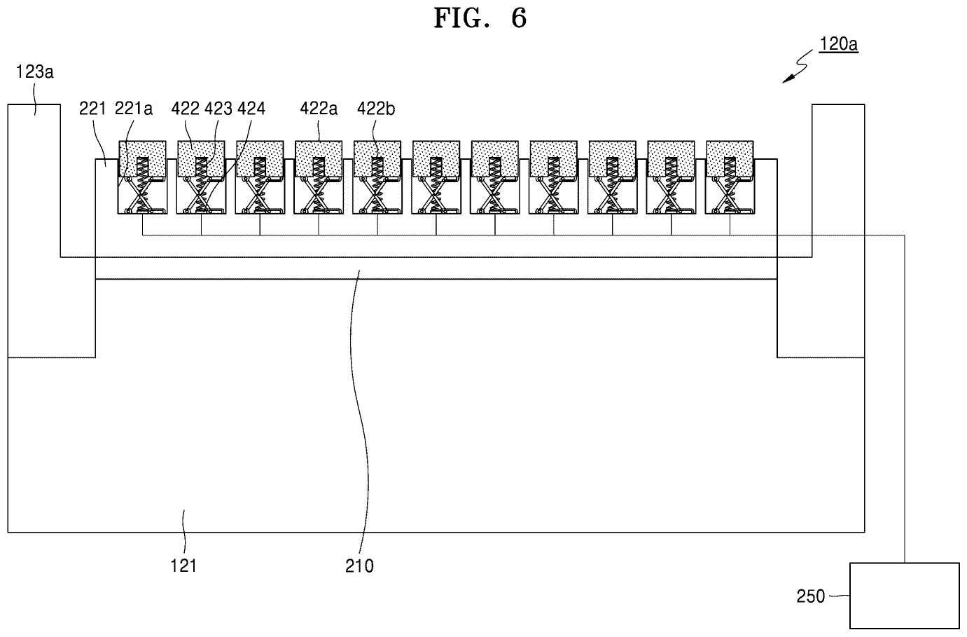

FIG. 6 is a cross-sectional view schematically illustrating an example of the substrate supporting unit of FIG. 1.

Referring to FIG. 6, a substrate supporting unit 120a may include a base plate 121, a chucking member 420 (e.g., a chuck), and a bonding layer 210. The base plate 121 and the bonding layer 210 of FIG. 6 may be the same as the base plate 121 and the bonding layer 210 of FIG. 2, and thus, repeated descriptions thereof may be omitted.

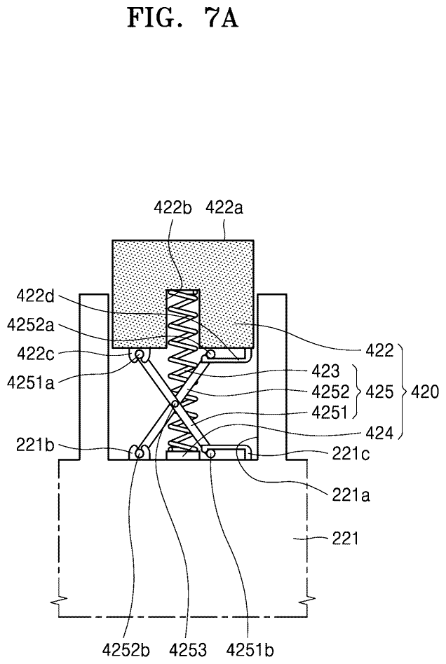

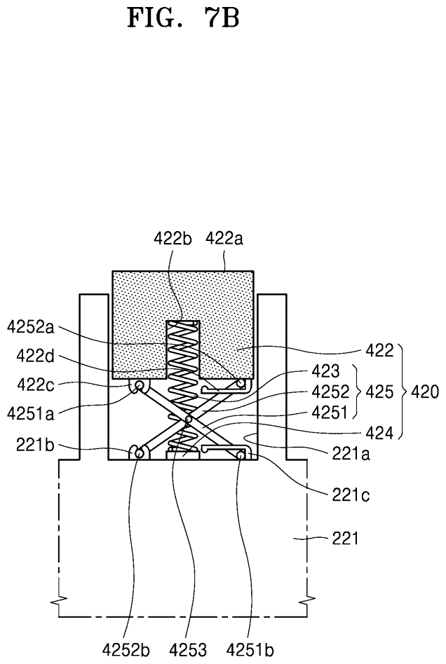

The chucking member 420 may include, for example, a plurality of supporting units 422, a body unit 221, a displacement allowance unit 425 (e.g., a displacement allower) (see FIGS. 7A-B), a pressure sensing unit 224, and a control unit 250. The pressure sensing unit 224 and the control unit 250 of FIG. 6 may be the same as the pressure sensing unit 224 and the control unit 250 of FIG. 2, and thus, repeated descriptions thereof may be omitted.

A plurality of supporting units 422 may support a substrate W in direct contact with the substrate W. The plurality of supporting units 422 may individually move toward the base plate 121, based on a bent appearance of the substrate W by a weight of the substrate W. Even when the substrate W is bent or strained, the plurality of supporting units 222 may uniformly support the entire substrate W.

When the pressing of the plurality of supporting units 422 by the substrate W is released, the plurality of supporting units 222 may return to original positions due to the displacement allowance unit 425.

Each of the plurality of supporting units 422 may include an upper surface 422a directly contacting the substrate W, a lower surface disposed to be opposite to the upper surface 422a, and a side surface connecting the upper surface to the lower surface. The upper surface 422a of the supporting unit 422 may be formed to be flat, and the substrate W may be stably mounted thereon.

A groove 422b may be formed in each supporting unit 422. The groove 422b may be recessed by a certain depth from a lower surface of the supporting unit 422 in a direction toward the upper surface 422a. A restoration unit 423 (e.g., a restorer such as, for example, an elastic body) may be disposed in each groove 422b, and thus, the supporting unit 422 may elastically move in a vertical direction. A depth and a width of the groove 422b may be optimized based on a size and an elastic characteristic of the restoration unit 423 used.

An upper end 2251a of a first moving part 4251 (see FIGS. 7A-B) of the displacement allowance unit 425 may be fixed to a lower surface of the supporting unit 422, and an upper end 4252a of a second moving part 4252 of the displacement allowance unit 425 may slide. This will be described below.

The body unit 221 may be a structure which accommodates the plurality of supporting units 422 and may be configured so that each supporting unit 422 moves in a vertical direction. The body unit 221 may include a plurality of accommodating spaces 221a. Each of the accommodating spaces 221a may be designed to accurately correspond to a shape of an individual supporting unit 422, and thus, may allow the vertical-direction movement of the supporting unit 422 and may limit the side-direction movement of the supporting unit 422.

A lower end 4252b (see FIGS. 7A-B) of the second moving part 4252 may be fixed to a lower surface of an accommodating space 221a of the body unit 221, and a lower end 4251b of the first moving part 4251 may slide. This will be described below.

The displacement allowance unit 425 may be disposed between the supporting unit 422 and the body unit 221 and may control and limit the vertical movement of the supporting unit 422. The displacement allowance unit 425 may provide a displacement control mechanism which is precise and stable compared to a method which uses only an elastic element.

The displacement allowance unit 425 may include, for example, the first moving part 4251, the second moving part 4252, and the restoration unit 423.

The first moving part 4251 and the second moving part 4252 may be disposed to intersect with each other and may be connected to each other to be rotatable at an intersection point 4253 (see FIGS. 7A-B) between the first moving part 4251 and the second moving part 4252. The intersection point 4253 may minimize friction and may enable a smooth rotational motion, based on fine bearing or flexure hinge.

The upper end 4251a of the first moving part 4251 may be rotatably fastened to a supporting fixing part 422c (see FIGS. 7A-B) which may be formed at (e.g., in or on) a lower surface of the supporting unit 422. Such a fastening method may, for example, minimize friction and may enable a free rotation, based on a precise pivot joint or a miniature ball bearing. The lower end 4251b of the first moving part 4251 may be inserted into a body slot 221c (see FIGS. 7A-B) formed on the lower surface of the accommodating space 221a of the body unit 221 and may perform a sliding motion. The sliding mechanism (e.g., the first moving part 4251 and the body slot 221c) may, for example, include an ultra-precise linear guide system, and thus, may minimize friction and may maintain a position accuracy of a nanometer level.

The lower end 4252b of the second moving part 4252 may be rotatably fastened to a body fixing part 221b (see FIGS. 7A-B) formed on the lower surface of the accommodating space 221a of the body unit 221. Such a fastening method, like an upper end of the first moving part 4251, may allow a free rotation, based on a precise pivot joint or a miniature ball bearing.

The upper end 4252a of the second moving part 4252 may be inserted into a supporting slot 422d (see FIGS. 7A-B) formed on a lower surface of the supporting unit 422 and may perform a sliding motion. The sliding mechanism (e.g., the second moving part 4252 and the body slot 221c), like the first moving part 4251, may include an ultra-precise linear guide system.

Based on a structural characteristic described above, when the supporting unit 422 moves upward and downward, each of the first moving part 4251 and the second moving part 4252 may move in directions opposite to each other while rotating with respect to a rotatable fastening point and may widen outward or narrow in an X-shape. The mechanism may allow the vertical movement of the supporting unit 422, and simultaneously, may effectively limit movement in a lateral direction. A rotatable fastening method may increase the flexibility of a system and may more decrease a concentration of stress and a smooth operation.

The restoration unit 423 may provide a force which returns the supporting unit 422 to an original position. The restoration unit 423 may, for example, be implemented as a system including a torsion spring or a self-restoring force, and the restoring force may be designed to be precisely adjusted.

The displacement allowance unit 425 may include rotation fastening as described above, and thus, stress occurring in an operation may be effectively dispersed. Also, the overall durability and lifetime of a system may be enhanced based on a reduction in concentration of stress.

FIGS. 7A and 7B are cross-sectional views illustrating an operation of the chucking member of the substrate supporting unit of FIG. 6.

Referring to FIG. 7A, an initial state of a chucking member 420 is illustrated. In this state, a supporting unit 422 may be disposed at an uppermost end and may be ready for accommodating a substrate. The displacement allowance unit 425 may have an X-shape, and the first moving part 4251 and the second moving part 4252 may intersect with each other at the intersection point 4253.

The upper end 4251a of the first moving part 4251 may be rotatably connected to the supporting fixing part 422c which may be formed at (e.g., in or on) a lower surface of the supporting unit 422. The lower end 4251b of the first moving part 4251 may be inserted into the body slot 221c formed on a lower surface of the accommodating space 221a of the body unit 221.

The lower end 4252b of the second moving part 4252 may be rotatably connected to the body fixing part 221b formed on the lower surface of the accommodating space 221a of the body unit 221, and the upper end 4252a of the second moving part 4252 may be inserted into the supporting slot 422d formed on the lower surface of the supporting unit 422.

The pressure sensing unit 224 may be disposed on the lower surface of the accommodating space 221a of the body unit 221 and may monitor pressure applied to the supporting unit 422 in real time.

FIG. 7B illustrates a state where the supporting unit 422 is lowered. FIG. 7B illustrates a state where a substrate is loaded onto a chucking member 420 and presses the supporting unit 422 with its weight. A structure of the displacement allowance unit 425 may be strained by lowering of the supporting unit 422.

In detail, the first moving part 4251 and the second moving part 4252 may widen outward in an X-shape while rotating about the intersection point 4253. The lower end 4251b of the first moving part 4251 may move outward along the body slot 221c, and the upper end 4252a of the second moving part 4252 may move outward along the supporting slot 422d.

Based on the mechanism, the supporting unit 422 may move in only a vertical direction, and movement in a horizontal direction may be effectively limited.

As the supporting unit 422 is lowered, the pressure sensing unit 224 may sense an increased pressure. Pressure data measured by the pressure sensing unit 224 may be transferred to the control unit 250 in real time and may be used to calculate a weight and a shape of a substrate.

Based on the mechanism described above, the chucking member 420 according to an embodiment may dynamically correspond to a fine shape change of a substrate, and thus, ultra-precise wafer control for a next-generation semiconductor manufacturing process may be possible. Also, embodiments of the present disclosure may respond to in real time a change in shape caused by thermal deformation or stress occurring in substrate processing, and thus, may considerably enhance the uniformity and yield rate of a process.

Hereinabove, non-limiting example embodiments of the present disclosure have been described with reference to the accompanying drawings. Example embodiment have been described by using the terms described herein, but these terms are merely used for describing examples and have not been used for limiting a meaning or limiting the scope of the present disclosure. Therefore, it may be understood by those of ordinary skill in the art that various modifications and other equivalent embodiments may be implemented, and the various modifications and the other equivalent embodiments are within the spirit and scope of the present disclosure.

While non-limiting example embodiments have been particularly shown and described, it will be understood that various changes in form and details may be made therein without departing from the spirit and scope of the present disclosure.

What is claimed is:

1. A substrate processing apparatus comprising:
a chuck configured to support a substrate;
a base plate configured to support the chuck; and
a bonding layer between the chuck and the base plate, the bonding layer attaching the chuck to the base plate,
wherein the chuck comprises:
a plurality of supports configured to contact the substrate;
an accommodating body that accommodates the plurality of supports;
at least one elastic body between the plurality of supports and the accommodating body; and
at least one pressure sensor configured to measure pressure applied by the substrate to the plurality of supports, and
wherein each of the plurality of supports is configured to individually move toward the base plate due to a weight of the substrate, based on a bent shape of the substrate.

2. The substrate processing apparatus of claim 1, wherein, in a case where the substrate stops pressing the plurality of supports, each of the plurality of supports return to an original position due to the at least one elastic body.

3. The substrate processing apparatus of claim 1, further comprising
a first moving part and a second moving part between the accommodating body and at least one from among the plurality of supports,
wherein the first moving part and the second moving part intersect with each other.

4. The substrate processing apparatus of claim 3, wherein the first moving part and the second moving part are rotatably connected to each other at an intersection point at which the first moving part intersects with the second moving part.

5. The substrate processing apparatus of claim 3, wherein an upper end of the first moving part is connected to a corresponding support from among the plurality of supports, and a lower end of the first moving part is configured to slide in the accommodating body, and
a lower end of the second moving part is connected to the accommodating body, and an upper end of the second moving part is configured to slide in the corresponding support.

6. The substrate processing apparatus of claim 5, wherein the accommodating body comprises a body slot into which the lower end of the first moving part is slidably inserted, and
the at least one from among the plurality of supports comprises a supporting slot into which the upper end of the second moving part is slidably inserted.

7. The substrate processing apparatus of claim 1, wherein the at least one elastic body comprises a spring or an elastic rubber.

8. The substrate processing apparatus of claim 1, further comprising a controller configured to calculate, based on pressure measured by the at least one pressure sensor based on a movement distance of each of the plurality of supports, a degree of bending of the substrate.

9. A substrate processing apparatus comprising:
a chuck configured to support a substrate by using an electrostatic force;
a base plate configured to support the chuck; and
a bonding layer between the chuck and the base plate, the bonding layer attaching the chuck to the base plate,
wherein the chuck comprises:
a plurality of supports configured to contact the substrate;
an accommodating body that accommodates the plurality of supports;
at least one displacement allower between the accommodating body and each of the plurality of supports, the at least one displacement allower configured to limit a vertical movement of each of the plurality of supports; and
at least one pressure sensor configured to measure pressure applied to the plurality of supports by the substrate, and
wherein each of the plurality of supports is configured to individually move toward the base plate due to a weight of the substrate, based on a bent shape of the substrate.

10. The substrate processing apparatus of claim 9, wherein the at least one displacement allower comprises:
a first moving part and a second moving part intersecting with each other; and
a restorer configured to return each of the first moving part and the second moving part to an original position.

11. The substrate processing apparatus of claim 10, wherein the first moving part and the second moving part are rotatably connected to each other at an intersection point at which the first moving part intersects with the second moving part.

12. The substrate processing apparatus of claim 10, wherein an upper end of the first moving part is connected to a corresponding support among the plurality of supports, and a lower end of the first moving part is configured to slide in the accommodating body, and
a lower end of the second moving part is connected to the accommodating body, and an upper end of the second moving part is configured to slide in the corresponding support.

13. The substrate processing apparatus of claim 12, wherein the accommodating body comprises a body slot into which the lower end of the first moving part is slidably inserted, and
the at least one from among the plurality of supports comprises a supporting slot into which the upper end of the second moving part is slidably inserted.

14. The substrate processing apparatus of claim 10, wherein the restorer comprises a spring or an elastic rubber.

15. A substrate processing apparatus comprising:
a housing including a processing space configured for processing a substrate;
a shower head in the housing and configured to supply an inner portion of the housing with a process gas for processing the substrate;
a substrate support under the shower head, in the housing, the substrate support configured to support the substrate; and
a plasma generator configured to generate plasma by using the process gas for processing the substrate,
wherein the substrate support comprises:
a chuck configured to support the substrate;
a base plate configured to support the chuck; and
a bonding layer between the chuck and the base plate, the bonding layer attaching the chuck to the base plate,
wherein the chuck comprises:
a plurality of supports configured to contact the substrate;
an accommodating body configured to accommodate the plurality of supports;
at least one displacement allower between the accommodating body and each of the plurality of supports, the at least one displacement allower configured to limit a vertical movement of each of the plurality of supports;
at least one pressure sensor configured to measure pressure applied to the plurality of supports by the substrate; and
a controller configured to calculate, based on pressure measured by the at least one pressure sensor based on a movement distance of each of the plurality of supports, a degree of bending of the substrate, and
wherein each of the plurality of supports is configured to individually move toward the base plate due to a weight of the substrate, based on a bent shape of the substrate.

16. The substrate processing apparatus of claim 15, wherein the at least one displacement allower comprises:
a first moving part and a second moving part intersecting with each other; and
a restorer configured to return each of the first moving part and the second moving part to an original position.

17. The substrate processing apparatus of claim 16, wherein the first moving part and the second moving part are rotatably connected to each other at an intersection point at which the first moving part intersects with the second moving part.

18. The substrate processing apparatus of claim 16, wherein an upper end of the first moving part is connected to a corresponding support among the plurality of supports, and a lower end of the first moving part is configured to slide in the accommodating body, and
a lower end of the second moving part is connected to the accommodating body, and an upper end of the second moving part is configured to slide in the corresponding support.

19. The substrate processing apparatus of claim 18, wherein the accommodating body comprises a body slot into which the lower end of the first moving part is slidably inserted, and
the at least one from among the plurality of supports comprises a supporting slot into which the upper end of the second moving part is slidably inserted.

20. The substrate processing apparatus of claim 16, wherein the restorer comprises a spring or an elastic rubber.
